(19) United States
(12) Patent Application Publication
(10) Pub. No.: US 2009/0316552 A1
(43) Pub. Date: Dec. 24, 2009

(54) Time interval analyzer which measures delay of read signal from medium

(75) Inventor: Toshiaki Kitano, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/453,546

(22) Filed: May 14, 2009

(30) Foreign Application Priority Data
Jun. 23, 2008 (JP) 2008-162983

(51) Int. Cl. G11B 20/10; G01R 29/00; G06F 19/00

(52) U.S. Cl. 369/53.31; 702/79; G9B/20.009

(57) ABSTRACT

A time interval analyzer includes a phase comparator which decides whether a measured signal contains a delay quantity for either a positive delay or a negative delay relative to a characteristic value, and a processor circuit which outputs a ratio of a number of the measured signals containing the positive delay and a number of the measured signals containing the negative delay.

### INCORPORATION BY REFERENCE

This application is based upon and claims the benefit of priority from Japanese Patent Application No. 2008-162983 which was filed on Jun. 23, 2008, the disclosure of which is incorporated herein in its entirety by reference.

### BACKGROUND OF THE INVENTION

1. Field of the Invention

The present invention relates to a time interval analyzer and measurement method for that time interval analyzer, and relates in particular to a time interval analyzer and its measurement method for measuring the difference between the phase of measured signals and a characteristic value.

2. Description of Related Art

A time interval analyzer is a device that measures by how much of a deviation quantity the phase of a measured signal deviates from a characteristic value serving as the standard. Utilizing a time interval analyzer to measure the phase accuracy or jitter of the measured signal, allows correcting for example the write characteristics of magnetic disk devices and the write signal of optical disk devices.

One example of this time interval analyzer is shown in patent document Japanese Patent Application Laid Open No. 2001-289892. The patent document discloses a jitter measurement device and a method for that device as one example of a time interval analyzer. FIG. 8 shows a flow chart illustrating the measurement method for the jitter measurement device. As shown in FIG. 8, data serving as the measured signal is input (step S101), and the difference between the data and characteristic value is calculated (step S102). The difference in the calculated results is then stored in the storage means (step S103). Then, if there is no specified number of data to input (step S104), then the process flow returns to step SI 01, and if the input of a specified number of data is finished, the calculated difference results are then read out. The average value of the calculated difference results is next calculated (step S105). The difference between this average value and each of the calculated difference results is found (step S106). The effective value for the difference between the each of the calculated difference results and the average value is then found (step S107).

### SUMMARY

However, the technology disclosed in the patent document requires many computations for each and every sample data. More specifically, the technology disclosed in patent document performs subtraction processing respectively in steps S102 and S106, and performs addition and division in step S105. The patent document therefore requires at least one addition and two subtractions for one sample data, and for a sample quantity set as n, requires that addition processing or subtraction processing be performed 3n times. So in the patent document, if the number of samples is increased, then the processing performance must be increased by three times for each additional sample increase. Therefore, when the frequency of the measured signal becomes higher, some type of countermeasure such as thinning out the measured signal edges is needed due to the time required to process the computations and these countermeasures cause a drop in measurement accuracy.

One exemplary aspect of the time interval analyzer of the present invention includes a phase comparator to decide if the measured signal contains a delay quantity for either a positive delay or a negative display relative to a characteristic value; and a processor circuit to output the ratio of the number of measured signals having a positive delay relative to the number of measured signals having a negative delay as the measurement results.

Another exemplary aspect of the time interval analyzer of the present invention includes an analog/digital signal converter to synchronize the measured signal with the sampling clock, and output the signal level as a digital value; a phase comparator to decide based on the digital value, whether or not the measured signal contains a delay quantity for either a positive delay or a negative display relative to a characteristic value; and a processor circuit to output the ratio of the number of measured signals having a positive delay and the number of measured signals having a negative delay as the measurement results.

One exemplary aspect of the measurement method for the time interval analyzer of the present invention decides whether or not the measured signal contains a delay quantity for either a positive delay or a negative display relative to a characteristic value, and calculates the ratio of the number of measured signals having a positive delay relative to the number of measured signals having a negative delay as the measurement results.

The time interval analyzer and measurement method of the present invention decides if the relation of the measured signal phase to the characteristic value is a positive delay or a negative delay, and outputs the ratio of the number of positive delay samples to the number of negative delay samples as the measurement results. In other words, in the time interval analyzer and measurement method of this invention the increase rate in the number of samples is the same as the required increase rate in the processing capacity. The time interval analyzer and measurement method of the present invention is therefore capable of measuring a larger number of samples in a short time.

The time interval analyzer and measurement method of the present invention are therefore capable of measuring a larger number of samples in a short time.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a block diagram of an optical disk device containing the time interval analyzer of a first exemplary embodiment;

FIG. 2 is a drawing showing the relation between the write signal and the read signal in the optical disk device;

FIG. 3 is a flow chart showing the measurement sequence in the time interval analyzer of the first exemplary embodiment;

FIG. 4 is a drawing for describing the method for deciding a positive delay in the read signal in the phase comparator in the first exemplary embodiment;

FIG. 5 is a drawing for describing the method for deciding a negative delay in the read signal in the phase comparator in the first exemplary embodiment;

FIG. 6 is a drawing for describing the method for correcting the write signal in the time interval analyzer of the first exemplary embodiment when inspection results with a value larger than 1 were obtained;

FIG. 7 is a drawing for describing the method for correcting the write signal in the time interval analyzer of the first exemplary embodiment when inspection results with a value smaller than 1 were obtained; and

FIG. 8 is a flow chart showing the measurement sequence in the time interval analyzer of a related art.

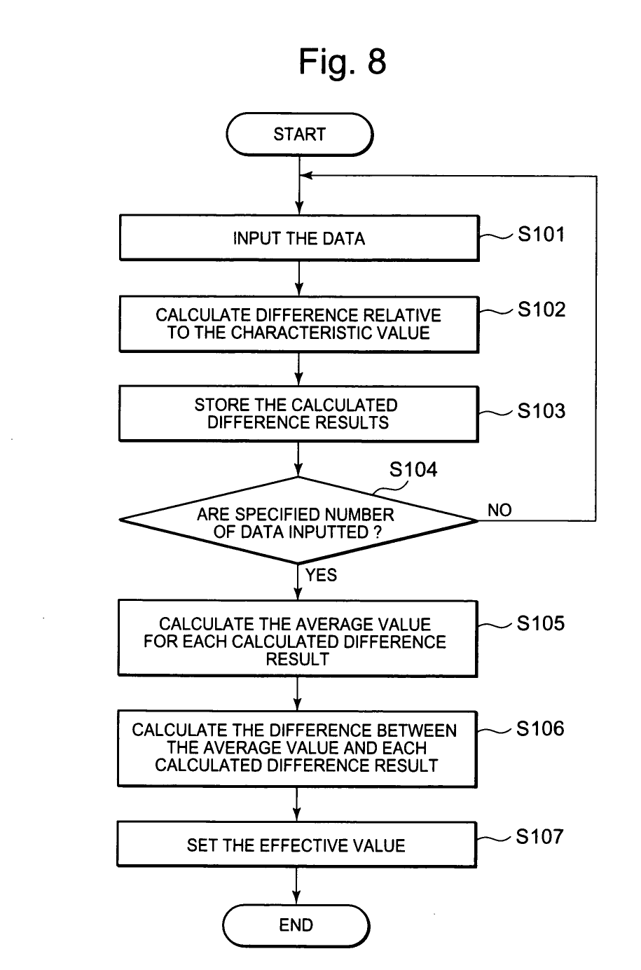

### DETAILED DESCRIPTION OF THE EXEMPLARY EMBODIMENTS

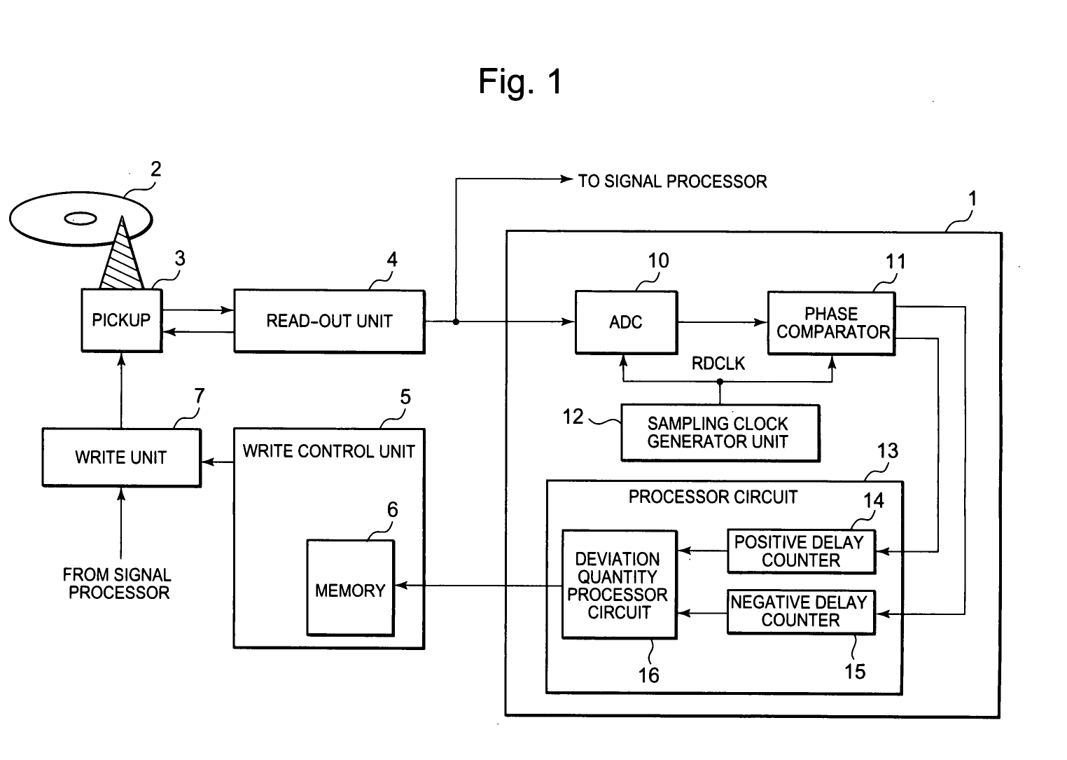

FIG. 1 is a block diagram of the time interval analyzer 1 of an exemplary embodiment. The time interval analyzer 1 of FIG. 1 is a time interval analyzer that utilizes the read signal from the optical disk device as the measured signal. Therefore, in addition to the time interval analyzer 1, the exemplary embodiment, as shown in FIG. 1 further includes an optical disk 2, a pickup 3, a read unit 4, a write control circuit 5, and a write unit 7.

The optical disk 2 is an optical disk meeting standards such as for CD-R, CD-RW, DVD±R, DVD±RW, DVD-RAM, etc. The optical disk 2 contains channels called grooves. Data called pits are stored in these grooves.

To write data, the pickup 3 emits pulsed laser light for writing according to a write signal output by the write unit 7, and uses this pulsed laser light to write data onto the optical disk 2. To read data, the pickup 3 emits a laser light for reading called, read power from the read unit 4, receives reflected light obtained by laser light reflected from the laser optical disk 2, and outputs a read signal to the read unit 4 according to that reflected light.

The read unit 4 controls the pickup 3 during data read and conveys the read signal obtained by way of the pickup 3 to subsequent circuit stages (such as the signal processor unit {not shown in drawing}).

The write control circuit 5 contains a memory 6 for storing control information. This control information is for example information on write settings called write strategy. The write control circuit 5 outputs a control signal to the write unit 7 for correcting the write signal characteristics according to the write strategy stored in the memory 6.

The write unit 7 outputs a write signal according to the data write signal sent from the prior stage circuit (such as signal processor unit {not shown in drawing}). The write unit 7 at this time corrects the write signal characteristics according to the control signal output from the write control circuit 5.

In this type of optical disk device, the time interval analyzer 1 measures the read signal (measured signal) output from the read unit 4, and outputs deviation amount information used in the write strategy adjustment in the write control circuit 5. The read signal is set as an analog signal. The time interval analyzer 1 is next described in detail. As shown in FIG. 1, the time interval analyzer 1 includes an analog/digital converter 10, a phase comparator 11, a sampling clock generator unit 12, and a processor circuit 13.

The analog/digital converter 10 synchronizes the read signal input as an analog signal, with the sampling clock (e.g. sampling clock RDCLK), makes a sampling, and outputs the signal level at that time as a digital value.

The phase comparator 11 decides whether or not the read signal contains a delay quantity for either a positive delay or a negative delay for a preset characteristic value. More specifically, the phase comparator 11 detects the zero cross timing where a first digital value corresponding to the current clock of the sampling clock RDCLK and a second digital value corresponding to the clock before the sampling clock RDCLK span a standard value, compares the absolute values for the first digital value and the second digital value at the zero cross timing, and decides based on the comparison results whether there is a positive value or a negative value. The operation of the phase comparator 11 is described in detail later on.

The sampling clock generator unit 12 generates the sampling clock RDCLK utilized in the analog/digital converter 10 and the phase comparator 11.

The processor circuit 13 outputs the results from dividing the number of read signals with a positive delay, and the number of read signals with a negative delay as the measurement result. The processor circuit 13 includes a positive delay counter 14, a negative delay counter 15, and a deviation quantity processor circuit 16. The positive delay counter 14 counts the number of read signals where the phase comparator 11 decided a positive delay occurred, and outputs the first count value. The negative delay counter 15 counts the number of read signals where the phase comparator 11 decided a negative delay occurred, and outputs the second count value. The deviation quantity processor circuit 16 refers to the first count value from the positive delay counter 14 and the second count value from the negative delay counter 15, and outputs the ratio of the first count value to the second count value as the measurement results.

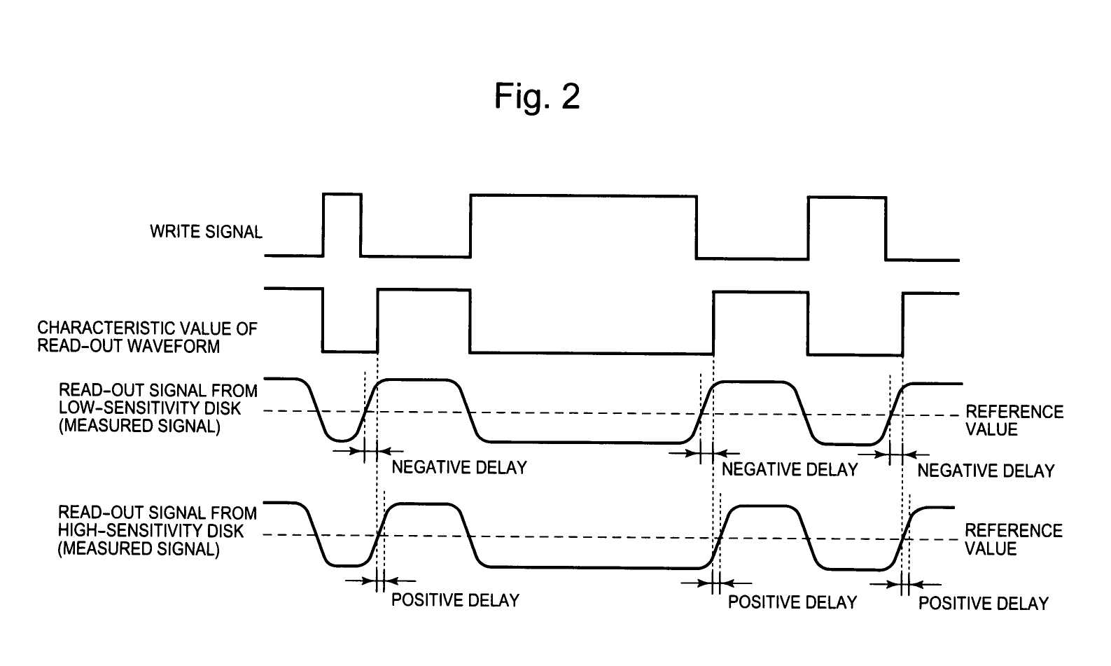

FIG. 2 shows one example of the relation of the write signal output from the write unit 7, to the read signal that was read out according to the data written in the optical disk 2 based on this write signal. The read signal characteristics are also described here.

The optical disk 2 as shown in FIG. 2 contains high-sensitivity portions and low-sensitivity portions due to variations among production lots and differences in material among individual products and disk manufacturers. Moreover, even on the same disk, there were sections with different sensitivity. Further, the sensitivity also differed according to the recording (write) temperature. When writing on a disk possessing these types of variations based on one write signal, differing read signals will then be generated according to these variations on the optical disk 2. As shown in the example in FIG. 2, read signals from a low-sensitivity disk will contain a negative delay in the rising portion versus the characteristic value of the read signal obtained when there were no variations. Read signals from a high-sensitivity disk on the other hand will contain a positive delay in the rising portion versus the characteristic value of the read signal obtained when there were no variations. On optical disks, variations in sensitivity for example will occur relative to the heat of the laser light which is a characteristic variation, and variations will occur in the pit length even when formed by the same amount of laser irradiation time. Phase errors in the read signal occur due to these variations.

The time interval analyzer 1 outputs the ratio of the number of positive delays and negative delays as the measurement result. The optical disk device then adjusts the write strategy based on this measurement result, and corrects that write signal so that the specified write signal is obtained regardless of variations on the optical disk 2. The method for correcting the write signal on the optical disk device according to the measurement results as well as the operation of the time interval analyzer 1 are described next.

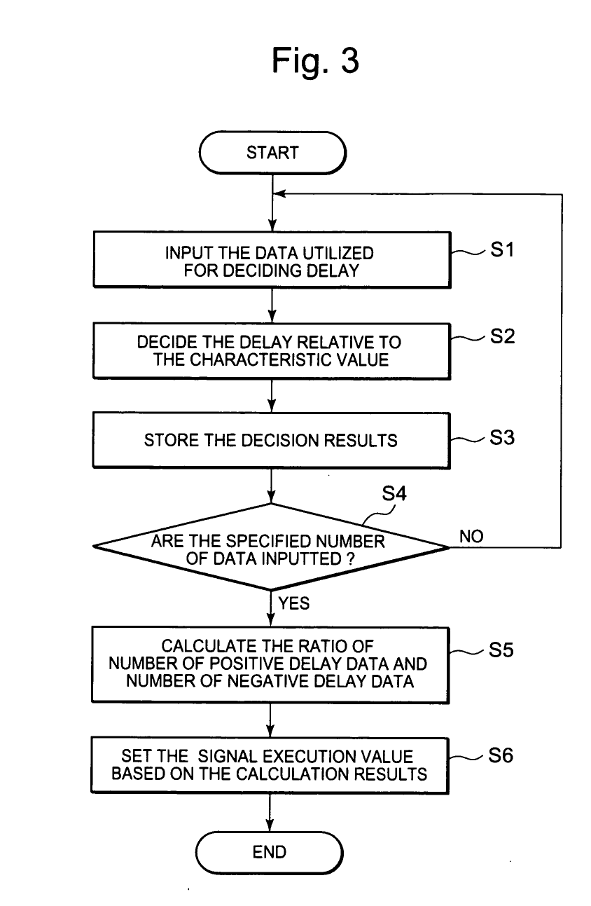

FIG. 3 is a flow chart showing first of all, the measurement sequence in the time interval analyzer 1 and is used to describe the operation of the time interval analyzer 1. As shown in FIG. 3, when the time interval analyzer 1 starts the measurement, the analog/digital converter 10 outputs a digital value according to the signal level of the measured signal, and the phase comparator 11 inputs data required for calculating the delay (step S1). The phase comparator 11 then decides the delay quantity of the read signal (step S2).

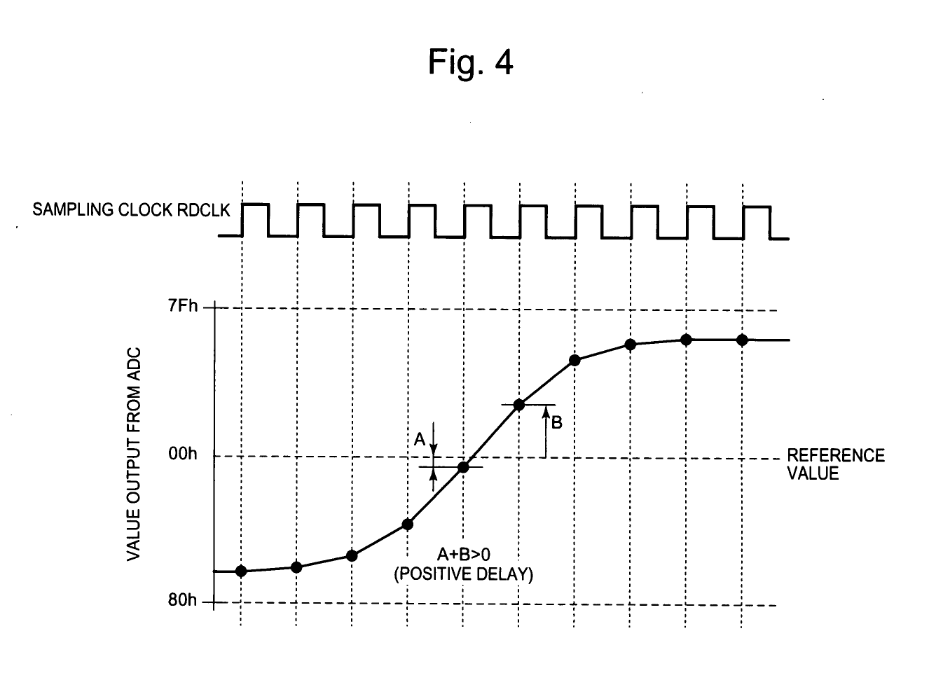

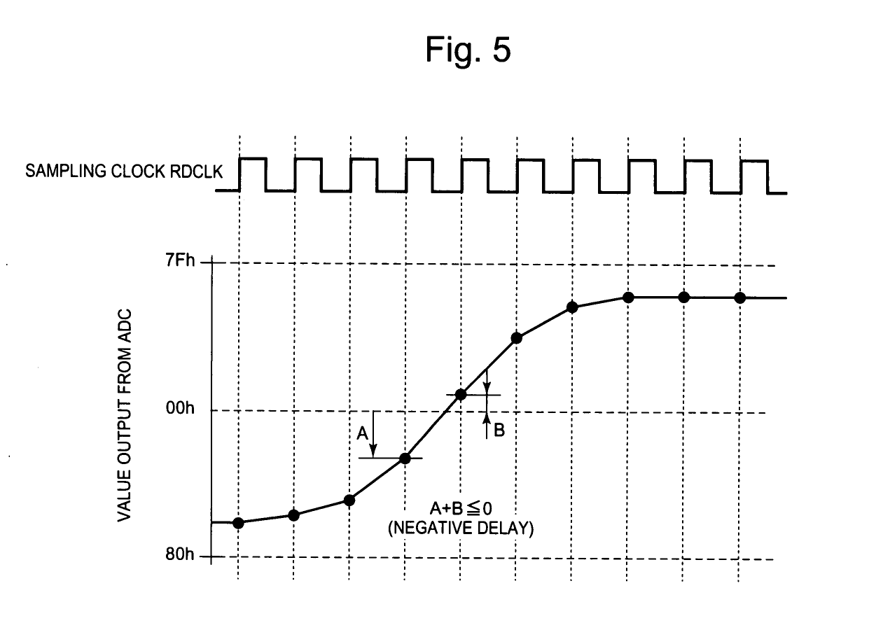

Methods for deciding the delay quantity in step S2 are described here while referring to FIG. 4 and FIG. 5. The transition in the digital signal value when the read signal contains a positive delay is shown in FIG. 4. The transition in the digital signal value when the read signal contains a negative delay is shown in FIG. 5. As shown in FIG. 4 and in FIG. 5, the digital signal is input to the phase comparator 11 at each rising edge of sampling clock RDCLK. In the exemplary embodiment, the phase comparator 11 at this time sets 00h (0 in decimal notation) forming the center value, as the reference value among the obtained range of values output by the analog/digital converter 10 (80h to 7Fh in hexadecimal notation; −128 to +127 in decimal notation).

The phase comparator 11 then refers to the first digital value corresponding to the current clock pulse of sampling clock RDCLK and the second digital value corresponding to the previous sampling clock RDCLK. The phase comparator 11 then inputs the first digital value and second digital value if they are spanning the reference value. The phase comparator 11 then decides based on the first digital value and second digital value that were input, whether the read signal delay is a positive delay or a negative delay relative to the characteristic value.

The point in time where the first digital value and second digital value span the reference value (or more accurately the point in time where the reference value intersects a straight line joining the first digital value and second digital value) is called the zero cross timing.

In the exemplary embodiment, the values output by the analog/digital converter 10 are positive values higher than the reference value and negative values lower than the reference value. The highest ranking bit of positive values is 0 when expressed in binary notation, and the highest ranking bit of negative values is 1 when expressed in binary notation. The phase comparator 11 therefore detects the zero cross timing by checking the highest ranking bit of values output by the analog/digital converter 10, and detecting the point in time where the highest ranking bit changes from a 0 to a 1, or from a 1 to a 0. If the analog/digital converter 10 outputs values from 00h to FFh (0 to 255 in decimal notation), and if the reference value is set to 0Fh (127 in decimal notation), then the zero cross timing is detected as the timing where results comparing the size of values output by analog/digital converter 10 and reference value 0Fh are now inverted.

In the example in FIG. 4, when the first digital value is set as A (point where value is negative relative to the reference value), and the second digital value is set as B (point where value is positive relative to the reference value), then A+B>0. Therefore, when the read signal is a waveform such as shown in FIG. 4, the phase comparator 11 then decides that the read signal contains a positive delay relative to the characteristic value.

In the example in FIG. 5 on the other hand, when the first digital value is set as A (point where value is negative relative to the characteristic value), and the second digital value is set as B (point where value is positive relative to the characteristic value), then A+B=<0. Therefore, when the read signal is a waveform such as shown in FIG. 5, the phase comparator 11 decides that the read signal contains a negative delay relative to the characteristic value.

The values output by the analog/digital converter 10 in the exemplary embodiment are positive values or negative values so addition is used to compare the absolute values for the first digital value and the second digital value. However if the values output by the analog/digital converter 10 are values from 00h to FFh (0 to 255 in decimal notation) and 0Fh (127 in decimal notation) is set as the reference value, then the absolute values of the first digital value and second digital value are compared by subtracting a first absolute value showing the difference between the first digital value and reference value, from a second absolute value showing the difference between the second digital value and reference value, and then deciding whether the subtraction results are positive or negative.

The positive delay counter 14 or the negative delay counter 15 counts and stores results from the phase comparator 11 (step S4). More specifically, the phase comparator 11 increments the first count value of the positive delay counter 14 by one, in case that the comparator 11 decides that a positive delay has occurred at the edge of the read signal. On the other hand, the phase comparator 11 increments the second count value of the negative delay counter 15 by one, in case that the comparator 11 decides that a negative delay has occurred at the edge of the read signal. The positive delay counter 14 and the negative delay counter 15 respectively count the number of times that positive delays and negative delays occur.

The deviation quantity processor circuit 16 refers to (or checks) the first count value of positive delay counter 14 and the second count value of negative delay counter 15, and then continuously performs steps S1-S3 by the analog/digital converter 10, the phase comparator 11, the positive delay counter 14 and the negative delay counter 15 until the number of measurement samples (or number of read signals for measurement) has reached the specified value (step 4). When the number of measurement samples then reaches the specified value, the deviation quantity processor circuit 16 refers to (or checks) the second count value output by positive delay counter 14 and the negative delay counter 15, calculates the ratio of positive delay data quantity to the negative delay data quantity by dividing the first count value by the second count value (step S5), and outputs the division results as the measurement results. If the first count value at this time is greater than the second count value, then the measurement result are a value larger than 1. If the first count value on the other hand is less than the second count value, then the measurement result is a value smaller than 1.

Aside from the above calculation method (first calculation method (first count value/second count value)), the method for calculating the ratio of the first count value and the second count value includes: a second calculation method (second count value/first count value), a third calculation method ((first count value−second count value)/(first count value+second count value)×100), a fourth calculation method (first count value/(first count value+second count value)), and a fifth calculation method (second count value/(first count value+second count value)). An appropriate method is selected from among these methods according to what results are wanted in a system utilizing the time interval analyzer 1 or according to the type of measured signal.

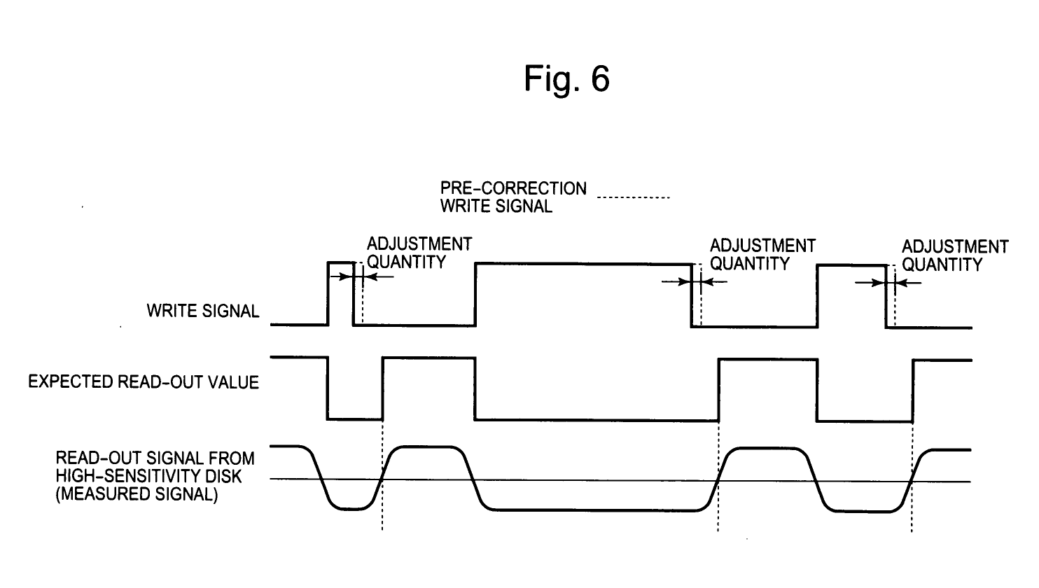

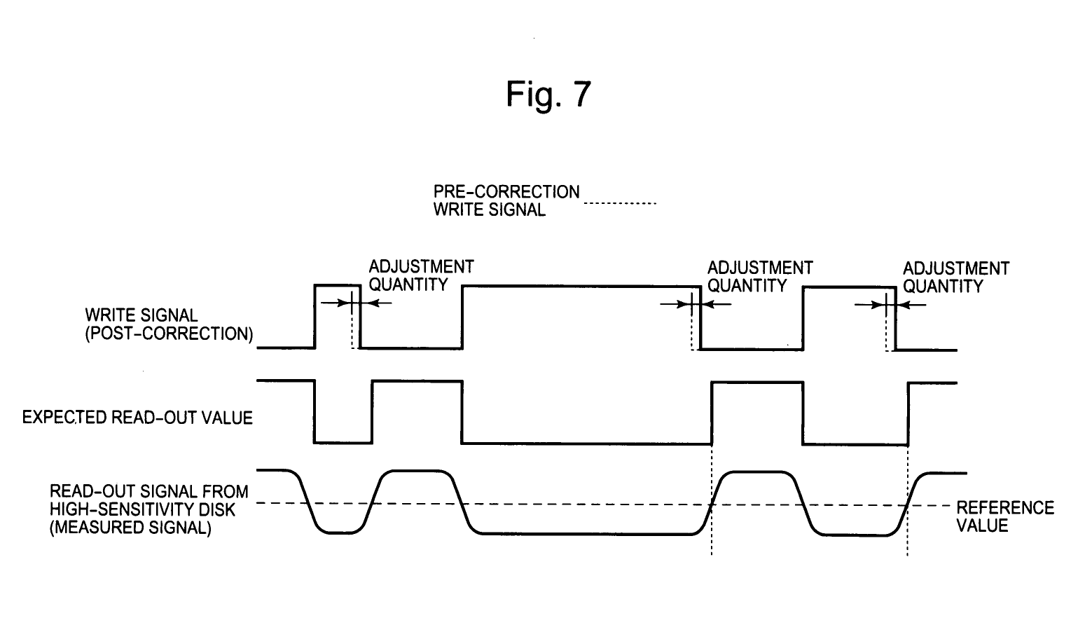

The operation of the time interval analyzer 1 was described above. A write signal execution value is set in the optical disk device based on the value from the measured results (step S6). More specifically, the optical disk device rewrites the write strategy stored in the memory 6 based on the measurement results. The optical disk device does not rewrite the write strategy if the measurement result is 1. The write control circuit 5 performs the rewrite of the write strategy. Here, FIG. 6 and FIG. 7 show the relation between the write signal and the read signal after the write strategy was changed. FIG. 6 is a drawing showing the relation between the write signal and the read signal for the case where the measurement result was larger than 1. FIG. 7 is a drawing showing the relation between the write signal and the read signal for the case where the measurement result was smaller than 1.

As shown in FIG. 6, if the measurement result is larger than 1, then the write control circuit 5 corrects the write strategy so that the pulse width of the write signal becomes shorter. The length of the pits formed on the optical disk are in this way made shorter so that the positive delay in the read signal is corrected, and the delay in the read signal relative to the characteristic value is eliminated.

On the other hand as shown in FIG. 7, if the measurement result is smaller than 1, then the write control circuit 5 corrects the write strategy so that the pulse width of the write signal becomes longer. The length of the pits formed on the optical disk are in this way made longer so that the negative delay in the read signal is corrected, and the delay in the read signal relative to the characteristic value is eliminated.

The extent to which the value in the measurement results from time interval analyzer 1 sets the write signal correction quantity must be decided beforehand in the evaluation.

The time interval analyzer 1 as described in the above exemplary embodiment finds only whether the delay quantity of the measured signal is a positive delay or a negative delay by addition or subtraction, and calculates the ratio of number of samples with positive delays and number of samples with negative delays as the measurement result. The number of samples and the number of times that the number of samples is added or is subtracted therefore attains the same increase rate in the time interval analyzer 1. There are therefore no pressing demands on processing capacity in the time interval analyzer 1 of the exemplary embodiment due to an increase in the number of samples, and the number of samples can easily be increased. Moreover, there is no increase in the number (cross quantity) of time-consuming division operations in the time interval analyzer 1 of the exemplary embodiment even if there is an increase in the number of samples. An increase in the number of samples therefore does not cause an increase in the measurement time in the time interval analyzer 1 of the exemplary embodiment. The measurement time can also be shortened. Further, power consumption by the circuits can also be reduced by lowering the processing load.

The technology disclosed in patent document for example found the measurement results from: n number of subtractions (step S102) and, n-1 additions as well as one division (step S105), and n number of subtractions (step S106) when measuring n number of samples. The time interval analyzer 1 of the exemplary embodiment however is capable of finding the measurement results from n number of additions or subtractions (step S2) and, one division (step S5).

Unlike the time interval analyzers of the related art, the time interval analyzer 1 of the exemplary embodiment does not require a memory for storing delay quantities. A delay quantity found by division generally includes a decimal figure in that delay quantity value. Storing a value including a decimal figure into the memory requires many bits to store one value. Storing these types of values therefore requires a memory with a large capacity. A large capacity memory utilizes a large circuitry surface area and internalizing this memory causes the problem that the circuitry surface area becomes larger in the time interval analyzer 1. Another problem is that the expansion in memory capacity becomes drastic when the number of measurement samples was increased.

In contrast, to the time interval analyzers of the related art, the time interval analyzer 1 of the exemplary embodiment stores the delay quantity decision results by counting operations using the positive delay counter 14 and the negative delay counter 15. The time interval analyzer 1 of the exemplary embodiment is capable of storing decision results on a larger number of samples in a small circuitry surface area and without requiring a large capacity memory such as utilized in the related art. The time interval analyzer 1 of the exemplary embodiment therefore has a small circuitry surface area compared to time interval analyzers of the related art. The increase in circuitry surface area of the counters due to increasing the number of samples exerts almost no effect on the circuitry surface area in the time interval analyzer 1.

A measurement method for a time interval analyzer includes determining whether a measured signal contains a delay quantity for either a positive delay or a negative delay relative to a characteristic value, and obtaining a ratio of a number of the measured signal containing the positive delay and a number of the measured signal containing the negative delay.

The present invention is not limited by the above exemplary embodiments and applicable changes may be made as needed without departing from the spirit and the scope of the invention. For example, the exemplary embodiments described applying the time interval analyzer to an optical disk device however, the time interval analyzer may be operated autonomously. Moreover, the invention is not limited to optical disk devices and may be utilized in a wide range of applications such as correcting write characteristics in magnetic disks, and measuring jitter in digital circuits.

Further, it is noted that Applicant's intent is to encompass equivalents of all claim elements, even if amended later during prosecution.

What is claimed is:

1. A time interval analyzer, comprising:
a phase comparator which decides whether a measured signal contains a delay quantity for either a positive delay or a negative delay relative to a characteristic value; and
a processor circuit which outputs a ratio of a number of measured signals containing the positive delay and a number of measured signals containing the negative delay.

2. The time interval analyzer according to claim 1, further comprising:
an analog/digital converter which samples the measured signal to output a signal level as a digital value in synchronization with a sampling clock,
wherein the phase comparator detects a zero cross timing when a first digital value corresponding to a clock pulse of the sampling clock and a second digital value corresponding to a previous clock pulse of the sampling clock span a reference value, and compares an absolute value of the first digital value and an absolute value of the second digital value at the zero cross timing, to identify the positive delay or the negative delay.

3. The time interval analyzer according to claim 1, wherein the processor circuit includes:
a positive delay counter which counts a number of the positive delay;
a negative delay counter which counts a number of the negative delay; and
a deviation quantity processor circuit which calculates a ratio of a first count value output by the positive delay counter and a second count value output by the negative delay counter.

4. The time interval analyzer according to claim 1, further comprising:
a write control circuit which corrects a waveform of a write signal onto an optical disk according to the ratio,
wherein the measured signal comprises a read signal generated based on pits formed on the optical disk.

5. A time interval analyzer, comprising:
an analog/digital converter which samples a measured signal to output a signal level as a digital value in synchronization with a sampling clock;
a phase comparator which decides based on the digital value whether the measured signal contains a delay quantity for either a positive delay or a negative delay relative to a characteristic value; and
a processor circuit which outputs a ratio of a number of measured signals containing the positive delay and a number of measured signals containing the negative delay.

6. The time interval analyzer according to claim 5,
wherein the phase comparator detects a zero cross timing when a first digital value corresponding to a clock pulse of the sampling clock and a second digital value corresponding to a previous clock pulse of the sampling clock span a reference value, and compares an absolute value of the first digital value and an absolute value of the second digital value at the zero cross timing, to identify the positive delay or the negative delay.

7. The time interval analyzer according to claim 5, wherein the processor circuit includes:
a positive delay counter which counts a number of the positive delay;
a negative delay counter which counts a number of the negative delay; and
a deviation quantity processor circuit which calculates a ratio of a first count value output by the positive delay counter and a second count value output by the negative delay counter.

8. The time interval analyzer according to claim 5, further comprising:
a write control circuit which corrects a waveform of a write signal onto an optical disk according to the ratio,
wherein the measured signal comprises a read signal generated based on pits formed on the optical disk.

9. A time interval analyzer, comprising:
an analog-to-digital converter which converts an analog signal obtained from an optical disk to a digital signal, based on a sampling clock;
a comparator which compares the digital signal with a reference signal to output either a first signal indicating a positive delay compared with the reference signal or a second signal indicating a negative delay compared with the reference signal, based on the sampling clock;
a first counter which counts a number of the first signal during a predetermined period;
a second counter which counts a number of the second signal during the predetermined period; and
a deviation quantity processor which obtains a delay amount based on the numbers counted by the first and second counters, in order to adjust a waveform of a write signal for conducting a write operation onto the optical desk to cancel the delay amount.
